(19) United States
(12) Patent Application Publication
(10) Pub. No.: US 2025/0226638 A1
(43) Pub. Date: Jul. 10, 2025

(54) LASER DEVICE AND METHOD FOR OPERATING A LASER DEVICE

(71) Applicant: ams-OSRAM International GmbH, Regensburg (DE)

(72) Inventors: Bilal SAIF, Regensburg (DE); Joerg Erich SORG, Regensburg (DE); Karolina TRACZYK, Bursins (CH); Radoslaw GANCARZ, Adliswil (CH)

(21) Appl. No.: 18/849,581

(22) PCT Filed: Jan. 30, 2023
(86) PCT No.: PCT/EP2023/052143

§ 371 Date: Sep. 23, 2024

(30) Foreign Application Priority Data
Mar. 24, 2022 (DE) 102022106950.8

(51) Int. Cl. H01S 5/026; H01S 5/042; H01S 5/22

(52) U.S. Cl. CPC H01S 5/0264; H01S 5/042; H01S 5/22

(57) ABSTRACT

Disclosed herein is a laser device that includes at least one first ridge structure and at least one second ridge structure, wherein the first ridge structure is configured to emit laser radiation, the second ridge structure is configured to generate charge carriers in response to exposure to electromagnetic radiation, the second ridge structure is connectable or connected with a sense circuitry of the laser device, the first ridge structure extends parallel to a lateral direction, the second ridge structure extends parallel to the lateral direction, and the first ridge structure and the second ridge structure comprise the same materials. Furthermore, a method for operating a laser device is also disclosed.

### CROSS-REFERENCE TO RELATED APPLICATION(S)

This application is a national phase of International Patent Application No. PCT/EP2023/052143 filed on Jan. 30, 2023, which claims priority to German Patent Application No. 10 2022 106950.8 dated Mar. 24, 2022, the contents of both of which are incorporated fully herein by reference.

### TECHNICAL FIELD A laser device and a method for operating a laser device are provided.

### BACKGROUND

For laser devices that emit laser radiation during operation, it is necessary to monitor the intensity of emitted laser radiation. For most applications the intensity of emitted laser radiation should not be higher than a given threshold value for example for safety reasons. If humans are around, it might be necessary to limit the laser emission to a certain intensity in order to avoid damages to the eyes of humans. It might also be desired to monitor the intensity of emitted laser radiation in order to keep the intensity constant. By monitoring the intensity of emitted laser radiation, the laser device can be controlled in such a way that the threshold value is not crossed. As an example, a photodiode can be employed to monitor emitted laser radiation.

### SUMMARY

It is an objective to provide a laser device that has a compact setup. It is further an objective to provide a method for operating a laser device that has a compact setup.

These objectives are achieved by the subject matter of the independent claims. Further developments and embodiments are described in dependent claims.

### BRIEF DESCRIPTION OF THE DRAWINGS

The following description refers to figures that may further illustrate and explain exemplary embodiments. Components that are functionally identical or have an identical effect are denoted by identical references. Identical or effectively identical components might be described only with respect to the figures where they occur first. Their description is not necessarily repeated in successive figures.

FIG. 1 shows an exemplary embodiment of the laser device and an exemplary embodiment of the method for operating a laser device.

FIG. 2 shows another exemplary embodiment of the laser device and another exemplary embodiment of the method for operating a laser device.

FIG. 3 shows another exemplary embodiment of the laser device and another exemplary embodiment of the method for operating a laser device.

FIGS. 4, 5A, 5B, 6, 7, 8, 9, 10 and 11 show parts of exemplary embodiments of the laser device.

FIGS. 12 and 13 show another exemplary embodiment of the laser device and another exemplary embodiment of the method for operating a laser device.

### DESCRIPTION

According to at least one embodiment of the laser device, the laser device comprises at least one first ridge structure. The first ridge structure can comprise a cavity that is arranged between two mirrors. The first ridge structure can comprise an active region that is configured to emit electromagnetic radiation during operation of the laser device. The first ridge structure can have an elongated shape. This can mean, that the first ridge structure has a main extension direction. The first ridge structure can form a ridge laser or a ridge waveguide laser.

According to at least one embodiment of the laser device, the laser device comprises at least one second ridge structure. The second ridge structure can comprise a cavity that is arranged between two mirrors. The second ridge structure can comprise an active region that is configured to emit electromagnetic radiation during operation of the laser device. The second ridge structure can have an elongated shape. This can mean, that the second ridge structure has a main extension direction. The second ridge structure can form a ridge laser or a ridge waveguide laser.

The laser device can thus be a multi-ridge laser device. The distance between the first ridge structure and the second ridge structure can be chosen to be large enough so that a current flow between the first ridge structure and the second ridge structure is inhibited. This can mean, that the distance between the first ridge structure and the second ridge structure is chosen to be large enough so that no current passes through a pnp junction formed by the first ridge structure and the second ridge structure.

The laser device can comprise at least two or at least three ridge structures in total.

According to at least one embodiment of the laser device, the first ridge structure is configured to emit laser radiation. The first ridge structure can be configured to emit laser radiation during operation of the laser device. The first ridge structure can be connected or connectable with a power source. The first ridge structure can be configured to emit laser radiation once it is provided with enough power by the power source to enable lasing. The first ridge structure can be configured to emit radiation through one of the two mirrors adjoining the cavity. The two mirrors can be arranged at opposite sides of the first ridge structure along the main extension direction of the first ridge structure.

According to at least one embodiment of the laser device, the second ridge structure is configured to generate charge carriers in response to exposure to electromagnetic radiation. The second ridge structure can comprise a pn-junction. In an active region around the pn-junction charge carriers can be generated in response to exposure to electromagnetic radiation. This means, that the second ridge structure can be configured to generate charge carriers once the second ridge structure is exposed to electromagnetic radiation.

According to at least one embodiment of the laser device, the second ridge structure is connectable or connected with a sense circuitry of the laser device. The sense circuitry can be configured to readout signals received from the second ridge structure. The sense circuitry can comprise sense electronics for analog processing or for digital processing with an analog-to-digital converter (ADC). That the second ridge structure is connectable with the sense circuitry can mean that it is possible to change between a state in which the second ridge structure is connected with the sense circuitry and a state in which the second ridge structure is disconnected from the sense circuitry. This can for example be achieved by connecting the second ridge structure with the sense circuitry via a switch. That the second ridge structure is connected with the sense circuitry can mean that the second ridge structure is permanently connected with the sense circuitry. The sense circuitry can be configured to provide output signals. The sense circuitry can comprise a comparator.

According to at least one embodiment of the laser device, the first ridge structure extends parallel to a lateral direction. The main extension direction of the first ridge structure can extend parallel to the lateral direction. The first ridge structure and the second ridge structure can be arranged on a substrate of the laser device. The substrate can have a main plane of extension. The lateral direction can extend parallel to the main plane of extension of the substrate.

According to at least one embodiment of the laser device, the second ridge structure extends parallel to the lateral direction. The main extension direction of the second ridge structure can extend parallel to the lateral direction. This can mean, that the first ridge structure and the second ridge structure extend parallel to each other or that the first ridge structure and the second ridge structure extend along one line. The first ridge structure and the second ridge structure can be arranged next to each other on the substrate.

According to at least one embodiment of the laser device, the first ridge structure and the second ridge structure comprise the same materials. This can mean, that the first ridge structure and the second ridge structure have the same composition. It is also possible that the first ridge structure and the second ridge structure have the same setup. The first ridge structure and the second ridge structure can have the same size. The first ridge structure and the second ridge structure can be produced in the same way. According to at least one embodiment of the laser device, the laser device comprises at least one first ridge structure, and at least one second ridge structure, wherein the first ridge structure is configured to emit laser radiation, the second ridge structure is configured to generate charge carriers in response to exposure to electromagnetic radiation, the second ridge structure is connectable or connected with an sense circuitry of the laser device, the first ridge structure extends parallel to a lateral direction, the second ridge structure extends parallel to the lateral direction, and the first ridge structure and the second ridge structure comprise the same materials.

The laser device has the advantage that the first ridge structure can be employed for the emission of laser radiation and the second ridge structure can be employed for a calibration of the emission of the first ridge structure. For this purpose, the second ridge structure is connectable or connected with the sense circuitry to detect radiation emitted by the first ridge structure. This is possible since there is a certain cross talk between the first ridge structure and the second ridge structure. This cross talk is used as a feedback. Once electromagnetic radiation is emitted by the first ridge structure, a part of this electromagnetic radiation also reaches the second ridge structure where charge carriers are generated in response to this electromagnetic radiation. These charge carriers are converted into an electrical signal which can be either processed in analog or digital domain. In each case, the sense circuitry can be configured to provide an output signal that depends on the number of charge carriers generated in the second ridge structure. The output signal provided by the sense circuitry can be employed for the calibration or monitoring of the emission of the first ridge structure. The output signal provided by the sense circuitry gives a measure for the intensity of laser radiation emitted by the first ridge structure. Thus, by monitoring the output signal, the intensity of laser radiation emitted by the first structure can be monitored. This allows to adopt the power provided by the power source to the first ridge structure in such a way that the intensity of the laser radiation emitted by the first ridge structure does not exceed a predefined threshold intensity.

The setup of the laser device has the advantage that no additional or external photodiode is required to monitor the emission of the first ridge structure. Instead, the second ridge structure is employed for this purpose. As the second ridge structure can have the same setup as the first ridge structure, the production process for the laser device is simplified. Since the second ridge structure can be a dummy ridge structure which in many cases is comprised by a laser device, the second ridge structure is not an additional component. Instead, a component that is required anyways, is used for monitoring the emission of the first ridge structure.

Furthermore, no optical elements are required to direct laser radiation emitted by the first ridge structure to a device that is configured to detect the laser radiation for monitoring. Instead, the cross talk between the first ridge structure and the second ridge structure is used. In this way, the second ridge structure can be employed to monitor the intensity of laser radiation emitted by the first ridge structure. Optical elements such as mirrors are not required in the setup of the laser device for directing radiation of the first ridge structure to the second ridge structure. Consequently, the laser device can have a compact setup.

Another advantage of the laser device is that the first ridge structure and the second ridge structure are arranged relatively close to each other. Therefore, the first ridge structure and the second ridge structure have a similar temperature during operation. In this way, errors in monitoring the intensity of emitted laser radiation due to temperature differences are avoided or reduced. Furthermore, the first ridge structure and the second ridge structure are exposed to the same environmental conditions. Thus, the first ridge structure and the second ridge structure age in the same or a similar way. This enables to avoid or reduce errors in monitoring the intensity of the emitted radiation due to different aging effects.

Another advantage of the laser device is that the first ridge structure and the second ridge structure can both be employed for different purposes. For example, the second ridge structure can also be connectable to a power source. Once the second ridge structure is provided with power it can be configured to emit laser radiation. This is possible since the second ridge structure can have the same setup and the same composition as the first ridge structure. In addition, the first ridge structure can be connectable with the sense circuitry or with a further sense circuitry of the laser device. Thus, the first ridge structure can be employed in the same way as the second ridge structure for detecting radiation emitted by the second ridge structure. This means, an alternate operation of the first ridge structure and the second ridge structure is possible. Both, the first ridge structure and the second ridge structure, can be configured to emit laser radiation and both, the first ridge structure and the second ridge structure, can be configured to detect radiation emitted by the other ridge structure due to cross talk. If the laser device comprises more than one first ridge structure and/or more than one second ridge structure, at least two ridge structures can be employed for monitoring the intensity of laser radiation emitted by one or more of the other ridge structures. Employing at least two ridge structures for monitoring the intensity has the advantage, that the integration time is reduced in comparison to the case that only one ridge structure or a photodiode is employed for monitoring the intensity. A reduced integration time leads to a reduced time required for a calibration.

Employing several ridge structures within one laser device has the advantages that a simplified lens setup can be employed as the ridge structures are arranged close to each other, that the resolution is increased, that the production process is very similar for different ridge structures and that the temperature during operation is very similar for the different ridges.

According to at least one embodiment of the laser device, the second ridge structure is arranged closer to a side surface of the laser device than the first ridge structure. The side surface can be an outer surface of the laser device. It is possible that the second ridge structure is arranged closer to one of the side surfaces of the laser device than the first ridge structure. For other side surfaces of the laser device, the first ridge structure and the second ridge structure can have the same distance to these side surfaces. The first ridge structure and the second ridge structure can be arranged next to each other or besides each other within the laser device. The first ridge structure and the second ridge structure can be arranged in one plane that extends parallel to a main plane of extension of the laser device. Consequently, during the production of the device, the process variation can be higher for the second ridge structure than for the first ridge structure. Therefore, the second ridge structure can be a dummy ridge structure which is not employed for the emission of laser radiation. An advantage of the laser device is that nevertheless the second ridge structure can be employed for monitoring the intensity of laser radiation emitted by the first ridge structure. Thus, the space within the device is used efficiently which can lead to a compact setup of the laser device.

According to at least one embodiment of the laser device, the first ridge structure and the second ridge structure have the same size and the same shape. This has the advantage that the first ridge structure and the second ridge structure can be produced in the same way. This simplifies the production of the laser device.

According to at least one embodiment of the laser device, the second ridge structure is configured to detect electromagnetic radiation emitted by the first ridge structure. This can mean, that charge carriers are generated in the second ridge structure in response to electromagnetic radiation emitted by the first ridge structure and reaching the second ridge structure. Generated charge carriers can be transferred to the sense circuitry. In this way, electromagnetic radiation emitted by the first ridge structure is detected by the second ridge structure. Electromagnetic radiation emitted by the first ridge structure can be received by the second ridge structure via cross talk. That the second ridge structure is configured to detect electromagnetic radiation emitted by the first ridge structure has the advantage that the second ridge structure can be employed to monitor the intensity of laser radiation emitted by the first ridge structure.

According to at least one embodiment of the laser device, the first ridge structure and the second ridge structure are monolithically integrated. The first ridge structure and the second ridge structure can for example be formed on the same substrate. That the first ridge structure and the second ridge structure are monolithically integrated has the advantage that the first ridge structure and the second ridge structure are arranged close enough to each other so that electromagnetic radiation emitted by the first ridge structure can reach the second ridge structure via cross talk. This allows to employ the second ridge structure for monitoring the intensity of radiation emitted by the first ridge structure.

According to at least one embodiment of the laser device, the first ridge structure and the second ridge structure extend parallel to each other. This can mean, that the main extension direction of the first ridge structure extends parallel to the main extension direction of the second ridge structure. The first ridge structure and the second ridge structure can be spaced apart from each other. That the first ridge structure and the second ridge structure extend parallel to each other has the advantage that the first ridge structure and the second ridge structure can easily be produced next to or besides each other in the same way. This simplifies the production process of the laser device.

According to at least one embodiment of the laser device, the first ridge structure and the second ridge structure extend along the same line. This can mean, that the first ridge structure and the second ridge structure are arranged next to each other along the same line. The main extension direction of the first ridge structure and the main extension direction of the second ridge structure can extend along the same line. The second ridge structure can have a shorter extension along this line than the first ridge structure. The arrangement of the first ridge structure and the second ridge structure along the same line has the advantage that the first ridge structure and the second ridge structure can be arranged within the laser device in a compact way.

According to at least one embodiment of the laser device, the second ridge structure is configured to emit laser radiation. The second ridge structure can be configured to emit laser radiation during operation of the laser device. The second ridge structure can be connected or connectable with the power source. The second ridge structure can be connected or connectable with a further power source. The second ridge structure can be configured to emit laser radiation once it is provided with enough power by the power source or the further power source to enable lasing. The second ridge structure can be configured to emit radiation through one of the two mirrors adjoining the cavity. The two mirrors can be arranged at opposite sides of the second ridge structure along the main extension direction of the second ridge structure. Advantageously, the second ridge structure can be employed for both the detection of electromagnetic radiation and the emission of electromagnetic radiation.

According to at least one embodiment of the laser device, the first ridge structure is configured to generate charge carriers in response to exposure to electromagnetic radiation and the first ridge structure is connectable with the sense circuitry or with a further sense circuitry of the laser device. The first ridge structure can comprise a pn-junction. In an active region around the pn-junction charge carriers can be generated in response to exposure to electromagnetic radiation. This means, that the first ridge structure can be configured to generate charge carriers once the first ridge structure is exposed to electromagnetic radiation. That the first ridge structure is connectable with the sense circuitry or the further sense circuitry can mean that it is possible to change between a state in which the first ridge structure is connected with the sense circuitry or the further sense circuitry and a state in which the first ridge structure is disconnected from the sense circuitry or the further sense circuitry. This can for example be achieved by connecting the first ridge structure with the sense circuitry or the further sense circuitry via a switch. The further sense circuitry can have the same setup as the sense circuitry. Advantageously, the first ridge structure can be employed to detect electromagnetic radiation emitted by the second ridge structure. Thus, the intensity of radiation emitted by the second ridge structure can be monitored.

According to at least one embodiment of the laser device, the first ridge structure and/or the second ridge structure are connected with the sense circuitry via a switch. It is thus possible that the first ridge structure is connected with the sense circuitry via a switch. It is also possible that the first ridge structure is connected with the further sense circuitry via a switch. It is also possible that the first ridge structure is connected with the sense circuitry via a switch and the second ridge structure is connected with the sense circuitry via the same switch or via a further switch. It is also possible that the first ridge structure is connected with the further sense circuitry via a switch and the second ridge structure is connected with the sense circuitry via a further switch. This enables, that both, the first ridge structure and the second ridge structure, can be employed for the detection of electromagnetic radiation. For example, the first ridge structure and the second ridge structure can be employed for the detection of electromagnetic radiation alternatingly.

According to at least one embodiment of the laser device, the first ridge structure and/or the second ridge structure are connected with a power source via a switch. It is thus possible that the first ridge structure is connected with the power source via a switch. It is also possible that the second ridge structure is connected with a further power source via a switch. It is also possible that the first ridge structure is connected with the power source via a switch and the second ridge structure is connected with the power source or with the further power source via a further switch. The power source and/or the further power source can be comprised by the laser device. Advantageously, both the first ridge structure and the second ridge structure can be employed for the emission of laser radiation. For example, the first ridge structure and the second ridge structure can be employed for the emission of laser radiation alternatingly.

According to at least one embodiment of the laser device, the laser device comprises at least one third ridge structure that has the same properties as the second ridge structure. This has the advantage that the second and the third ridge structure can be employed for the detection of electromagnetic radiation emitted by the first ridge structure. This reduces the required integration time. The second ridge structure and third ridge structure can be connected or connectable with the same sense circuitry.

According to at least one embodiment of the laser device, the laser device comprises more than one first ridge structure. This allows to employ more than one ridge structure for the emission of laser radiation. Furthermore, at least two ridge structures can be employed for the detection of electromagnetic radiation.

According to at least one embodiment of the laser device, the first ridge structure is electrically insulated from the second ridge structure. In this way, is possible to provide the first ridge structure with power while the second ridge structure detects electromagnetic radiation emitted by the first ridge structure.

According to at least one embodiment of the laser device, the first ridge structure is connectable with the sense circuitry or with a further sense circuitry of the laser device via a switch, and the first ridge structure and the second ridge structure are connectable with a power source via a switch, respectively. This means, the first ridge structure is connectable with the power source via a switch and the second ridge structure is connectable with the power source via a further switch. This allows to employ the first ridge structure for the emission of radiation and to employ both the first ridge structure and the second ridge structure for the detection of electromagnetic radiation.

Furthermore, a method for operating a laser device is provided. The laser device can preferably be operated by the method for operating a laser device described herein. This means all features disclosed for the laser device are also disclosed for the method for operating a laser device and vice-versa.

According to at least one embodiment of the method for operating a laser device, the method comprises providing a first ridge structure of the laser device with power so that laser radiation is emitted by the first ridge structure. The first ridge structure can be provided with power by a power source. The power source can be comprised by the laser device or it can be an external power source.

According to at least one embodiment of the method for operating a laser device, the method comprises connecting a second ridge structure of the laser device with an sense circuitry of the laser device. The second ridge structure can be connected with the sense circuitry by closing a switch which is arranged between the second ridge structure and the sense circuitry. It is also possible that the second ridge structure is permanently connected with the sense circuitry.

According to at least one embodiment of the method for operating a laser device, the second ridge structure is configured to generate charge carriers in response to exposure to electromagnetic radiation. For example, the second ridge structure is exposed to electromagnetic radiation emitted by the first ridge structure during operation of the laser device, where the emitted electromagnetic radiation is transmitted to the second ridge structure via cross talk. Since the second ridge structure is connected with the sense circuitry, charge carriers generated in the second ridge structure can be transferred to the sense circuitry. The charge carriers generated in the second ridge structure are transferred to the sense circuitry as an analog signal. During operation, the sense circuitry processes this analog signal. The sense circuitry can provide an output signal. The output signal provides a measure for the intensity of radiation emitted by the first ridge structure. Before a first operation of the laser device, the laser device can be calibrated. A calibration can comprise a measurement of the amount of charge carriers generated in the second ridge structure in response to the emission of laser radiation by the first ridge structure. The calibration allows to provide a correlation between the amount of charge carriers generated in the second ridge structure and the intensity of laser radiation emitted by the first ridge structure. This calibration can be employed for the operation of the laser device. Thus, from the output signal provided by the sense circuitry it is possible to determine the intensity of laser radiation emitted by the first ridge structure.

According to at least one embodiment of the method for operating a laser device, the first ridge structure extends parallel to a lateral direction.

According to at least one embodiment of the method for operating a laser device, the second ridge structure extends parallel to the lateral direction.

According to at least one embodiment of the method for operating a laser device, the first ridge structure and the second ridge structure comprise the same materials.

According to at least one embodiment of the method for operating a laser device, the method comprises providing a first ridge structure of the laser device with power so that laser radiation is emitted by the first ridge structure, and connecting a second ridge structure of the laser device with an sense circuitry of the laser device, wherein the first ridge structure extends parallel to a lateral direction, the second ridge structure extends parallel to the lateral direction, and the first ridge structure and the second ridge structure comprise the same materials.

The method for operating a laser device has the same advantages as the laser device. No additional or external photodiode is required to monitor the intensity of laser radiation emitted by the first ridge structure. Instead, the second ridge structure can be employed to monitor the intensity of laser radiation emitted by the first ridge structure. This leads to a compact setup of the laser device. If in total more than two ridge structures are employed, the integration time can be reduced which means that less time is required for monitoring or calibrating the intensity of laser radiation emitted by the first ridge structure.

According to at least one embodiment of the method for operating a laser device, charge carriers generated in the second ridge structure are transferred to the sense circuitry at the same time as laser radiation is emitted by the first ridge structure. This means, the charge carriers are generated in the second ridge structure in response to exposure to electromagnetic radiation emitted by the first ridge structure. The transfer of the generated charge carriers to the sense circuitry at the same time as laser radiation is emitted by the first ridge structure enables an instantaneous monitoring of the intensity of laser radiation emitted by the first ridge structure. This enables to correct unwanted values of the intensity of emitted laser radiation instantaneously. Furthermore, a continuous monitoring of the intensity of radiation emitted by the first ridge structure is possible.

According to at least one embodiment of the method for operating a laser device, the transfer of the charge carriers takes place at a time that is not employed for imaging in an imaging process. An imaging process can be a process where an image is projected by the laser device. The image can for example be projected by scanning over an area. Times that are not employed for imaging can be times where no part of the image is provided by the laser device. This can for example be dark times. Another example are the times during which optical elements of the laser device change their direction of movement. These optical elements can be mirrors for projecting the emitted laser radiation. These optical elements require time to change their direction of movement in the projection process. This time is usually not employed to project the image. However, the laser device can emit laser radiation during this time. This laser radiation can be employed for the monitoring or calibration process. This means, the second ridge structure detects electromagnetic radiation emitted by the first ridge structure during a time that is not employed for imaging in the imaging process. The second ridge structure can detect electromagnetic radiation emitted by the first ridge structure during the whole time that is not employed for imaging in the imaging process or during at least one time frame within the time that is not employed for imaging in the imaging process.

According to at least one embodiment of the method for operating a laser device, the transfer of the charge carriers takes place at a time that is employed for imaging in an imaging process.

According to at least one embodiment of the method for operating a laser device, signals provided by the sense circuitry are employed for calibrating the emission of the first ridge structure. Signals provided by the sense circuitry that is connected to the second ridge structure relate to the intensity of laser radiation emitted by the first ridge structure. Thus, from the signals provided by the sense circuitry it can be determined if the intensity of emitted laser radiation is within a desired range or not. If the intensity of emitted laser radiation is not within the desired range, parameters of the power source can be adjusted so that the intensity of emitted laser radiation changes. In this way, a calibration of the intensity of emitted laser radiation is possible.

According to at least one embodiment of the method for operating a laser device, the second ridge structure is provided with power so that laser radiation is emitted by the second ridge structure, and the first ridge structure is connected with the sense circuitry or with a further sense circuitry of the laser device. The second ridge structure can either be employed to detect electromagnetic radiation emitted by the first ridge structure or the second ridge structure can be employed for the emission of laser radiation. During the time, that the second ridge structure is provided with power so that laser radiation is emitted by the second ridge structure, the first ridge structure can be employed for detecting electromagnetic radiation emitted by the second ridge structure. The first ridge structure can be employed for detecting electromagnetic radiation in the same way as described above for the second ridge structure. The second ridge structure can be employed for the emission of laser radiation in the same way as described above for the first ridge structure. This means, both ridge structures can have two different functions, namely the emission of laser radiation and the detection of electromagnetic radiation. Both functions can be employed alternatingly. In this way, the space within the laser device is used efficiently so that the laser device can have a compact setup.

According to at least one embodiment of the method for operating a laser device, signals provided by the sense circuitry or the further sense circuitry are employed for calibrating the emission of the second ridge structure. Signals provided by the sense circuitry or the further sense circuitry that is connected to the first ridge structure relate to the intensity of laser radiation emitted by the second ridge structure. Thus, from the signals provided by the sense circuitry or the further sense circuitry it can be determined if the intensity of emitted laser radiation is within a desired range or not. If the intensity of emitted laser radiation is not within the desired range, parameters of the power source can be adjusted so that the intensity of emitted laser radiation changes. In this way, a calibration of the intensity of emitted laser radiation is possible.

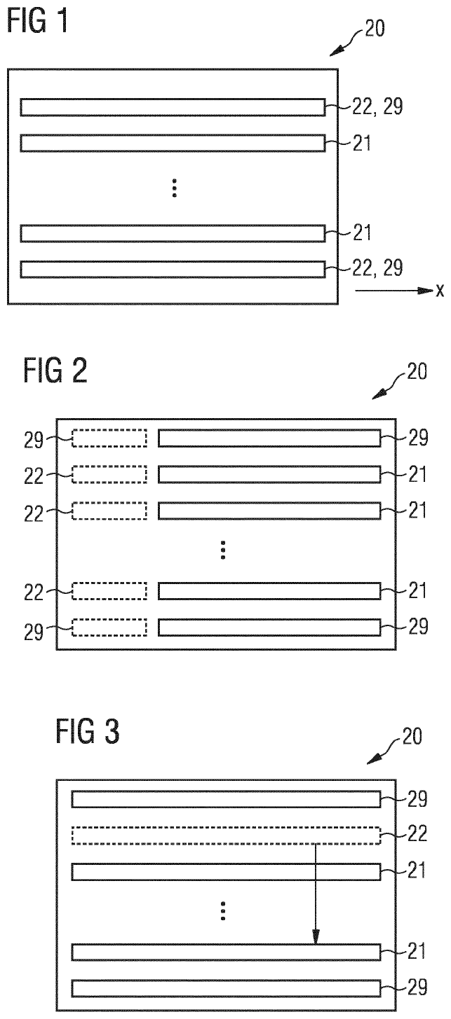

FIG. 1 shows a cross-section through an exemplary embodiment of the laser device 20. The laser device 20 comprises at least two first ridge structures 21 and two second ridge structures 22. The first ridge structures 21 are arranged next to each other. This means, FIG. 1 shows a top view on the laser device 20. That the laser device 20 can comprise more than two first ridge structures 21 is shown by the three dots arranged between the two first ridge structures 21. The first ridge structures 21 are arranged next to one of the second ridge structures 22. The other second ridge structure 22 is arranged next to the first ridge structures 21. The first ridge structures 21 are each configured to emit laser radiation. The second ridge structures 22 are each configured to generate charge carriers in response to exposure to electromagnetic radiation. The second ridge structures 22 are each connectable or connected with an sense circuitry 23 of the laser device 20. Thus, the second ridge structures 22 are configured to detect electromagnetic radiation emitted by the first ridge structures 21. Possible setups of the sense circuitry 23 are shown in FIGS. 5, 7 and 9.

The first ridge structures 21 each extend parallel to a lateral direction x. The second ridge structures 22 each extend parallel to the lateral direction x. Furthermore, the first ridge structures 21 and the second ridge structures 22 extend parallel to each other. The first ridge structures 21 and the second ridge structures 22 comprise the same materials. The first ridge structures 21 and the second ridge structures 22 also have the same size and the same shape. The first ridge structures 21 and the second ridge structures 22 are monolithically integrated. One of the second ridge structures 22 can also be regarded as a third ridge structure 28 that has the same properties as the other second ridge structure 22. The second ridge structures 22 are arranged closer to side surfaces 24 of the laser device 20 than the first ridge structures 21. Thus, the second ridge structures 22 can each be a dummy ridge structure 29.

With FIG. 1 also an exemplary embodiment of the method for operating a laser device 20 is described. The method comprises providing at least one of the first ridge structures 21 of the laser device 20 with power so that laser radiation is emitted by at least one of the first ridge structures 21. Furthermore, at least one of the second ridge structures 22 is connected with the sense circuitry 23. It is possible that both second ridge structures 22 are connected with the sense circuitry 23. Charge carriers that are generated in the second ridge structures 22 in response to the exposure to electromagnetic radiation emitted by the at least one first ridge structure 21 and transmitted via cross talk are transferred to the sense circuitry 23 at the same time as laser radiation is emitted by the first ridge structure 21. This means, the second ridge structures 22 are employed for monitoring the intensity of laser radiation emitted by the at least one first ridge structure 21. After a first calibration, from charge carriers generated by the electromagnetic radiation received by the second ridge structures 22 via cross talk, the intensity of the laser radiation emitted by the at least one first ridge structure 21 can be calculated. Thus, signals provided by the sense circuitry 23 can be employed for calibrating the emission of the at least one first ridge structure 21. In the embodiment of FIG. 1 it is possible that the first ridge structures 21 are only employed for the emission of laser radiation and that the second ridge structures 22 are only employed for the detection of electromagnetic radiation.

FIG. 2 shows a cross-section through another exemplary embodiment of the laser device 20. In comparison to the setup shown in FIG. 1, each ridge structure 21, 22 is divided into two parts. The laser device 20 comprises two dummy ridge structures 29, where one of the dummy ridge structures 29 is arranged at one side of the laser device 20 and the other dummy ridge structure 29 is arranged at an opposite side of the laser device 20. Each dummy ridge structure 29 is arranged next to one of the ridge structures 21, 22. Also, the dummy ridge structures 29 are divided into two parts. The two parts of each dummy ridge structure 29 extend along the same line. However, the two parts of each dummy ridge structure 29 have a different length along this line. The laser device 20 further comprises at least three first ridge structures 21. That the laser device 20 can comprise more than three first ridge structures 21 is shown by the dots between the first ridge structures 21. The first ridge structures 21 have a shorter extension along their main extension direction than in FIG. 1. Adjacent to each of the first ridge structures 21 one second ridge structure 22 is arranged. This means, in each case one first ridge structure 21 and one second ridge structure 22 extend along the same line. The second ridge structure 22 in each case has a shorter extension along this line than the first ridge structure 21. In each case, the first ridge structure 21 and the adjacent second ridge structure 22 are arranged spaced apart from each other. In each case, the first ridge structure 21 is electrically insulated from the second ridge structure 22. All first ridge structures 21 have the same size and the same setup. All second ridge structures 22 have the same size and the same setup. The first ridge structures 21 and the second ridge structures 22 comprise the same materials and have the same composition. The first ridge structures 21 and the second ridge structures 22 can have the same properties. Besides these differences in comparison to the embodiment shown in FIG. 1, the first ridge structures 21 and the second ridge structures 22 can have the same properties as described with FIG. 1.

The laser device 20 shown in FIG. 2 can be operated as described with FIG. 1. In the embodiment of FIG. 2 it is possible that the first ridge structures 21 are only employed for the emission of laser radiation and that the second ridge structures 22 are only employed for the detection of electromagnetic radiation. The embodiment shown in FIG. 2 has the additional advantage that both the first ridge structures 21 and the second ridge structures 22 are exposed to less process variation than the dummy ridge structures 29.

FIG. 3 shows a cross-section through another exemplary embodiment of the laser device 20. In comparison to the embodiment shown in FIG. 1, the laser device 20 of FIG. 3 comprises two dummy ridge structures 29. One of the dummy ridge structures 29 is arranged at one side of the laser device 20 and besides the other ridge structures 21, 22 and the other dummy ridge structure 29 is arranged at an opposite side of the laser device 20 and besides the other ridge structures 21, 22. The laser device 20 further comprises at least two first ridge structures 21 and at least one second ridge structure 22. In FIG. 3, the second ridge structure 22 is arranged on the other first ridge structures 21. It is however also possible to arrange the first ridge structures 21 and the second ridge structure 22 in another way.

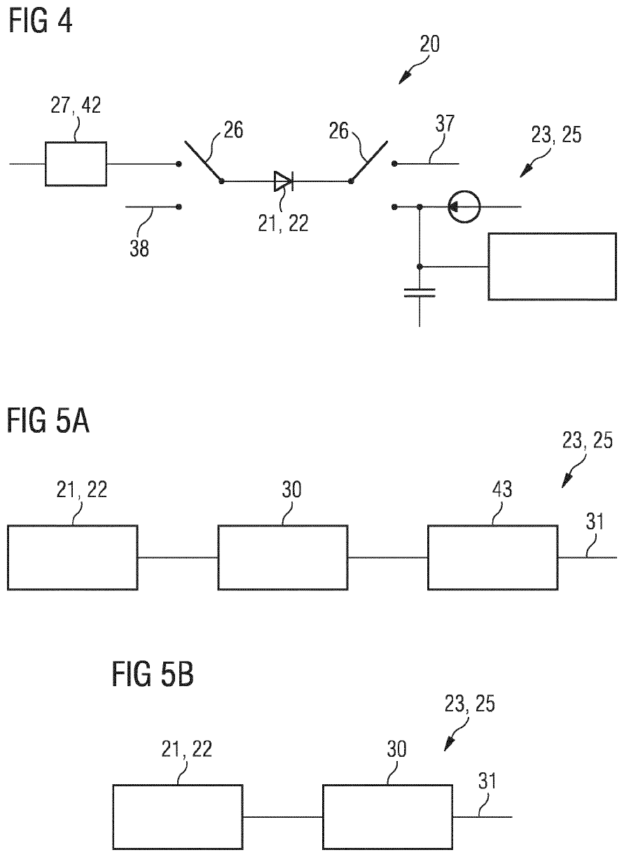

In the embodiment of FIG. 3 the at least one second ridge structure 22 is also configured to emit laser radiation. For this purpose, the at least one second ridge structure 22 is connectable with the power source 27 or with a further power source 42. The connection to the power source 27 is shown in FIG. 4. The first ridge structures 21 are configured to generate charge carriers in response to exposure to electromagnetic radiation and the first ridge structures 21 are connectable with the sense circuitry 23 or with a further sense circuitry 25 of the laser device 20. The connection with the sense circuitry 23 or the further sense circuitry 25 is shown in FIG. 4.

Thus, in the embodiment of FIG. 3 the first ridge structures 21 and the at least one second ridge structure 22 are all configured to emit laser radiation. Moreover, the first ridge structures 21 and the at least one second ridge structure 22 are all configured to detect electromagnetic radiation. The laser device 20 of FIG. 3 can therefore be operated as follows. At least one of the first ridge structures 21 is provided with power so that the first ridge structure 21 emits laser radiation. At the same time, the at least one second ridge structure 22 is connected with the sense circuitry 23 so that charge carriers generated by electromagnetic radiation from the first ridge structure 21 reaching the second ridge structure 22 via cross talk are transferred to the sense circuitry 23. In this way, the intensity of the laser radiation emitted by the first ridge structure 21 can be monitored. In a next step of the method for operating the laser device 20, at least one second ridge structure 22 is provided with power so that the second ridge structure 22 emits laser radiation. At the same time, at least one first ridge structure 21 is connected with the sense circuitry 23 or with the further sense circuitry 25 so that charge carriers generated by electromagnetic radiation from the second ridge structure 22 reaching the first ridge structure 21 via cross talk are transferred to the sense circuitry 23 or the further sense circuitry 25. In this way, the intensity of the laser radiation emitted by the second ridge structure 22 can be monitored. Thus, the first ridge structures 21 and the second ridge structures 22 of the laser device 20 shown in FIG. 3 can all be employed for in these two different modes. This is indicated by the arrow in FIG. 3.

Each of the first ridge structures 21 and the second ridge structures 22 can be operated in two different modes, either for emission of laser radiation or for detection of electromagnetic radiation. For these two different modes, different voltages are applied to the ridge structures 21, 22. The embodiment shown in FIG. 3 has the advantage that these different voltages are applied to all ridge structures 21, 22 of the laser device 20 after one another. Therefore, not only one ridge structure 21, 22 is exposed to these voltage changes, but the voltage changes are distributed over all ridge structures 21, 22 of the laser device 20.

With FIG. 4 a part of an exemplary embodiment of the laser device 20 is shown. FIG. 4 shows how the first ridge structures 21 and the second ridge structures 22 can be connected with the power source 27 and the sense circuitry 23. Thus, the ridge structure 21, 22 shown in FIG. 4 can be either a first ridge structure 21 or a second ridge structure 22, for example from the embodiment shown in FIG. 3. Between the power source 27 and the ridge structure 21, 22 a switch 26 is arranged. Furthermore, between the ridge structure 21, 22 and the sense circuitry 23 a switch 26 is arranged. The power source 27 can also be the further power source 42 and the sense circuitry 23 can also be the further sense circuitry 25. For the case that the ridge structure 21, 22 is operated so that it emits laser radiation, the switch 26 between the power source 27 and the ridge structure 21, 22 is closed. Furthermore, the side of the ridge structure 21, 22 that is not connected with the power source 27 is connected with a first potential 37. For the case that the ridge structure 21, 22 is operated so that it detects electromagnetic radiation, the switch 26 between the ridge structure 21, 22 and the sense circuitry 23 is closed. Furthermore, the side of the ridge structure 21, 22 that is connected with the sense circuitry 23 is connected with a second potential 38.

In FIG. 5A a part of an exemplary embodiment of the laser device 20 is shown. With FIG. 5A the connection of a first ridge structure 21 or a second ridge structure 22 to the sense circuitry 23 or the further sense circuitry 25 is shown. Thus, the component shown on the left side in FIG. 5A can be either a first ridge structure 21 or a second ridge structure 22. The ridge structure 21, 22 is connected with an amplifier 30 of the sense circuitry 23 or the further sense circuitry 25. The amplifier 30 is connected with an analog-to-digital converter 43 of the sense circuitry 23 or the further sense circuitry 25. The sense circuitry 23 or the further sense circuitry 25 can comprise an output 31 where digital output signals can be provided. In order to operate the ridge structure 21, 22 in such a way that electromagnetic radiation is detected, a positive or a negative voltage is applied to the ridge structure 21, 22.

In FIG. 5B a part of an exemplary embodiment of the laser device 20 is shown. The only difference to FIG. 5A is that the sense circuitry 23 or the further sense circuitry 25 is configured for analog signal processing. Thus, the sense circuitry 23 or the further sense circuitry 25 does not comprise an analog-to-digital converter. In FIG. 5B, the sense circuitry 23 or the further sense circuitry 25 comprises an amplifier 30. The sense circuitry 23 or the further sense circuitry 25 can comprise an output 31 where analog output signals can be provided.

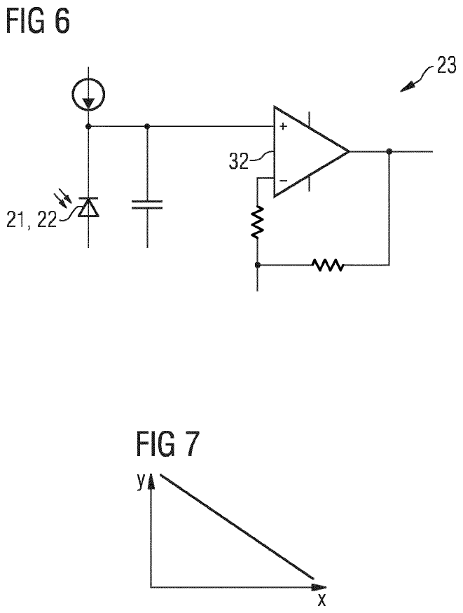

FIG. 6 shows an exemplary embodiment of the sense circuitry 23. The further sense circuitry 25 can have the same setup as the sense circuitry 23. The sense circuitry 23 is connected with a first ridge structure 21 or a second ridge structure 22 to which a voltage is applied. The sense circuitry 23 comprises a comparator 32. The sense circuitry 23 is configured to process the received signals in the analog domain.

FIG. 7 shows the response of the sense circuitry 23 shown in FIG. 6. In the diagram shown in FIG. 7 on the x-axis the intensity of the radiation to which the first ridge structure 21 or the second ridge structure 22 is exposed is plotted. On the y-axis the voltage provided by the sense circuitry 23 is plotted. For the embodiment of the sense circuitry 23 shown in FIG. 6, the response is inverse. This means, with an increasing intensity of the radiation, the voltage provided by the sense circuitry 23 decreases.

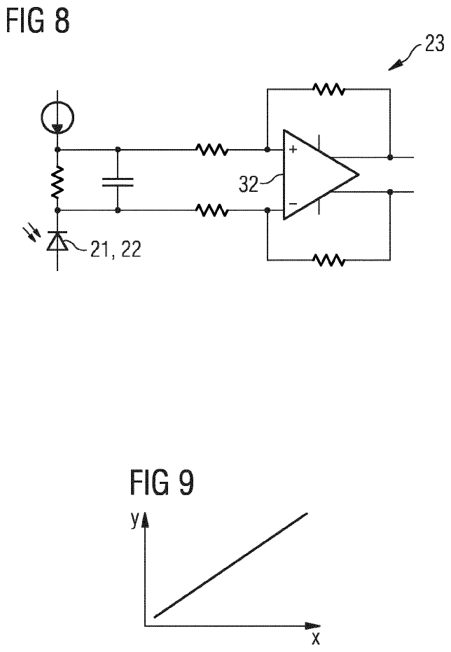

FIG. 8 shows another exemplary embodiment of the sense circuitry 23. The further sense circuitry 25 can have the same setup as the sense circuitry 23. The sense circuitry 23 is connected with a first ridge structure 21 or a second ridge structure 22 to which a voltage is applied. The sense circuitry 23 comprises a comparator 32. The sense circuitry 23 is configured to process the received signals in the analog domain.

FIG. 9 shows the response of the sense circuitry 23 shown in FIG. 8. In the diagram shown in FIG. 9 on the x-axis the intensity of the radiation to which the first ridge structure 21 or the second ridge structure 22 is exposed is plotted. On the y-axis the voltage provided by the sense circuitry 23 is plotted. For the embodiment of the sense circuitry 23 shown in FIG. 8, the response is linear. This means, with an increasing intensity of the radiation, the voltage provided by the sense circuitry 23 increases.

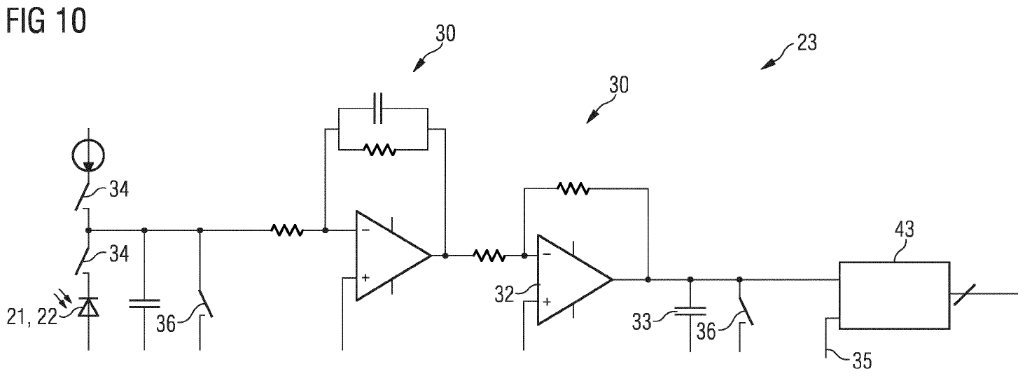

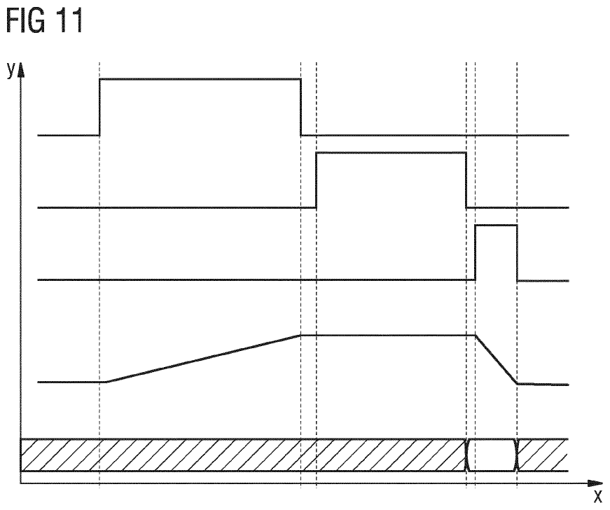

FIG. 10 shows another exemplary embodiment of the sense circuitry 23. The further sense circuitry 25 can have the same setup as the sense circuitry 23. The sense circuitry 23 is connected with a first ridge structure 21 or a second ridge structure 22 to which a voltage is applied. The sense circuitry 23 comprises two amplifiers 30, a hold capacitor 33, an analog-to-digital converter 43, first switches 34, a second switch 35 and third switches 36. The sense circuitry 23 is configured to process the received signals in the digital domain.

FIG. 11 shows a time diagram for the operation of the sense circuitry 23 shown in FIG. 10. On the x-axis the time is plotted. On the y-axis different parameters are plotted on top of each other. In the top line in the diagram the state of the first switch 34 is plotted. For each switch 26, the high value relates to the switch 26 being closed and the low value relates to the switch 26 being open. In the second line in the diagram the state of the second switch 35 is plotted. In the third line in the diagram the state of the third switch 36 is plotted. In the fourth line in the diagram the voltage at the hold capacitor 33 is plotted. In the last line in the diagram it is plotted when an output value is provided by the sense circuitry 23. This is the case after an integration time and a hold-and-convert time. The time when output values are provided by the sense circuitry 23 is marked as the region that is not marked with dashed lines.

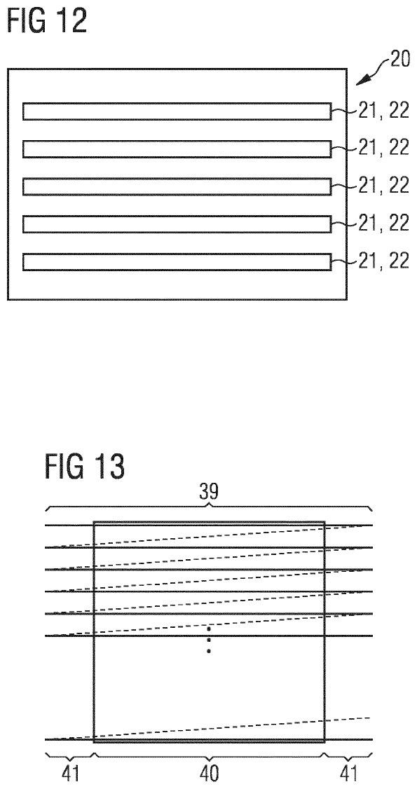

With FIGS. 12 and 13 another exemplary embodiment of the laser device 20 an another exemplary embodiment of the method for operating a laser device 20 are described. FIG. 12 shows a cross-section through the laser device 20. The laser device 20 comprises five ridge structures 21, 22. At least one of the ridge structures 21, 22 is a first ridge structure 21 and at least one of the ridge structures 21, 22 is a second ridge structure 22. The other three ridge structures 21, 22 can be any of a first ridge structure 21 or a second ridge structure 22. The five ridge structures 21, 22 are arranged as shown in FIG. 1. Each of the ridge structures 21, 22 is connectable via switches 26 as shown in FIG. 4.

With FIG. 13 it is described how the laser device 20 of FIG. 12 can be operated. The transfer of the charge carriers takes place at a time that is not employed for imaging in an imaging process. One ridge structure 21, 22 at a time is employed to project a part of an image 40 into a projection area 39. For this purpose, the laser radiation emitted by this ridge structure 21, 22 is deflected by optical elements such as a mirror according to a projection pattern. As an example, FIG. 13 shows a linear projection pattern. However, also other projection patterns are possible. For each row of the image 40 the optical elements require some time to change their direction of movement. Therefore, the image 40 provided is a smaller than the projection area 39. This leads to areas of the projection area 39 that are not employed for projecting the image 40. These areas are arranged at two sides of the projection area 39 and are referred to as overshoot regions 41. The basic idea of this embodiment is that during the time during which laser radiation is emitted into the overshoot regions 41, the ridge structures 21, 22 that are not emitting laser radiation are employed for the detection of emitted electromagnetic radiation.

During the time that laser radiation is emitted in at least one overshoot region 41, the remaining ridge structures 21, 22 are employed to monitor the emitted laser radiation. Therefore, this time that is not required for projecting the image 40 is efficiently used for monitoring or calibrating the emitted laser radiation. The detection of emitted electromagnetic radiation can take place during the emission of laser radiation into at least one of the overshoot regions 41 or into more than one overshoot region 41. The detection of emitted electromagnetic radiation can take place during the emission of laser radiation into the overshoot regions 41 arranged at one side of the image 40 or into all overshoot regions 41. At least one ridge structure 21, 22 that is not employed for the emission of laser radiation or more than one ridge structure 21, 22 that is not employed for the emission of laser radiation or all ridge structures 21, 22 that are not employed for the emission of laser radiation can be employed for the detection of electromagnetic radiation. As described with FIG. 3, each ridge structure 21, 22 can be employed for both the emission of laser radiation and the detection of electromagnetic radiation. The monitoring or calibration of a ridge structure 21, 22 can take place for only one of the overshoot regions 41, only for the other one of the overshoot regions 41 or for both overshoot regions 41.

For the detection of electromagnetic radiation, all ridge structures 21, 22 that are employed for the detection can be connected with the same sense circuitry 23. Thus, the current increases which reduces the required integration time. Therefore, as more than one, in the example of FIG. 13 four, ridge structures 21, 22 are employed for the detection of electromagnetic radiation, the time required for the monitoring or calibration is reduced.

It will be appreciated that the disclosure is not limited to the disclosed embodiments and to what has been particularly shown and described hereinabove. Rather, features recited in separate dependent claims or in the description may advantageously be combined. Furthermore, the scope of the disclosure includes those variations and modifications, which will be apparent to those skilled in the art. The term “comprising”, insofar it was used in the claims or in the description, does not exclude other elements or steps of a corresponding feature or procedure. In case that the terms “a” or “an” were used in conjunction with features, they do not exclude a plurality of such features. Moreover, any reference signs in the claims should not be construed as limiting the scope.

### REFERENCE NUMERALS

20 laser device
21 first ridge structure
22 second ridge structure
23 sense circuitry
24 side surface
25 further sense circuitry
26 switch
27 power source
28 third ridge structure
29 dummy ridge structure
30 amplifier
31 output
32 comparator
33 hold capacitor
34 first switch
35 second switch
36 third switch
37 first potential
38 second potential
39 projection area
40 image
41 overshoot region
42 further power source
43 analog-to-digital converter
x lateral direction

1. Laser device comprising:
at least one first ridge structure, and
at least one second ridge structure, wherein
the first ridge structure is configured to emit laser radiation,
the second ridge structure is configured to generate charge carriers in response to exposure to electromagnetic radiation,
the second ridge structure is connectable or connected with a sense circuitry of the laser device,
the first ridge structure extends parallel to a lateral direction,
the second ridge structure extends parallel to the lateral direction,
the first ridge structure and the second ridge structure comprise the same materials, and
the first ridge structure is connectable with the sense circuitry or with a further sense circuitry of the laser device via a switch, and the first ridge structure and the second ridge structure are connectable with a power source via a switch, respectively.

2. Laser device according to claim 1, wherein the second ridge structure is arranged closer to a side surface of the laser device than the first ridge structure.

3. Laser device according to claim 1, wherein the first ridge structure and the second ridge structure have the same size and the same shape.

4. Laser device according to claim 1, wherein the second ridge structure is configured to detect electromagnetic radiation emitted by the first ridge structure.

5. Laser device according to claim 1, wherein the first ridge structure and the second ridge structure are monolithically integrated.

6. Laser device according claim 1, wherein the first ridge structure and the second ridge structure extend parallel to each other.

7. Laser device according to claim 1, wherein the first ridge structure and the second ridge structure extend along the same line.

8. Laser device according to claim 1, wherein the second ridge structure is configured to emit laser radiation.

9. Laser device according to claim 1, wherein the first ridge structure is configured to generate charge carriers in response to exposure to electromagnetic radiation and the first ridge structure is connectable with the sense circuitry or with a further sense circuitry of the laser device.

10. Laser device according to claim 1, wherein the first ridge structure and/or the second ridge structure are connected with the sense circuitry via a switch.

11. Laser device according to claim 1, wherein the first ridge structure and/or the second ridge structure are connected with a power source via a switch.

12. Laser device according to claim 1, wherein the laser device comprises at least one third ridge structure that has the same properties as the second ridge structure.

13. Laser device according to claim 1, wherein the first ridge structure is electrically insulated from the second ridge structure.

14. Method for operating a laser device, the method comprising:
providing a first ridge structure of the laser device (with power so that laser radiation is emitted by the first ridge structure, and
connecting a second ridge structure of the laser device with an sense circuitry of the laser device, wherein
the second ridge structure is configured to generate charge carriers in response to exposure to electromagnetic radiation,
the first ridge structure extends parallel to a lateral direction,
the second ridge structure extends parallel to the lateral direction,
the first ridge structure and the second ridge structure comprise the same materials, and
the first ridge structure is connectable with the sense circuitry or with a further sense circuitry of the laser device via a switch, and the first ridge structure and the second ridge structure are connectable with a power source via a switch, respectively.

15. Method for operating a laser device according to claim 14, wherein charge carriers generated in the second ridge structure are transferred to the sense circuitry at the same time as laser radiation is emitted by the first ridge structure.

16. Method for operating a laser device according to claim 15, wherein the transfer of the charge carriers takes place at a time that is not employed for imaging in an imaging process.

17. Method for operating a laser device according to claim 14, wherein signals provided by the sense circuitry are employed for calibrating the emission of the first ridge structure.

18. Method for operating a laser device according to claim 14, wherein the second ridge structure is provided with power so that laser radiation is emitted by the second ridge structure, and the first ridge structure is connected with the sense circuitry or with a further sense circuitry of the laser device.

19. Method for operating a laser device according to claim 18, wherein signals provided by the sense circuitry or the further sense circuitry are employed for calibrating the emission of the second ridge structure.
